(19) United States
(12) Patent Application Publication
(10) Pub. No.: US 2024/0347484 A1
(43) Pub. Date: Oct. 17, 2024

(54) SEMICONDUCTOR PACKAGING DEVICE AND MANUFACTURING METHOD FOR SEMICONDUCTOR PACKAGING DEVICE

(71) Applicant: SHUNSIN TECHNOLOGY (ZHONG SHAN) LIMITED, Zhongshan (CN)

(72) Inventor: SHUN-HSING LIAO, Zhongshan City (CN)

(73) Assignee: SHUNSIN TECHNOLOGY (ZHONG SHAN) LIMITED, Zhongshan (CN)

(21) Appl. No.: 18/141,202

(22) Filed: Apr. 28, 2023

(30) Foreign Application Priority Data
Apr. 13, 2023 (CN) 202310398637.X

(51) Int. Cl. H01L 23/66; H01L 23/00; H01L 23/498

(52) U.S. Cl. CPC H01L 23/66; H01L 23/49816; H01L 23/49838; H01L 24/11; H01L 24/16; H01L 24/81; H01L 2223/6616; H01L 2223/6677; H01L 2224/11334; H01L 2224/16227; H01L 2224/81024; H01L 2224/81192; H01L 2924/182

(57) ABSTRACT

The present disclosure provides a semiconductor package device and a manufacturing method for semiconductor packaging device, the device includes a circuit substrate comprising a first surface and a second surface opposite to the first surface, and a circuit layer disposed between the first surface and the second surface, wherein both the first surface and the second surface are provided with bonding pads; an electronic component disposed on the first surface and electrically connected to the bonding pads of the first surface; a plurality of antenna components spanning the electronic component in a copper bridge manner and electrically connected to the bonding pads on the first surface; and a molding layer formed on the first surface of the circuit substrate, wherein the molding layer surrounds and exposes the plurality of antenna components, and covers the electronic component.

### FIELD

The present disclosure relates to a field of packaging design technology, in particular to a semiconductor packaging device and a manufacturing method for semiconductor packaging device.

### BACKGROUND

In recent years, due to the rapid development of semiconductor technology, the functions of chips are increasingly changing, and the demand for miniaturization of instruments and equipment is also increasing. Currently, antenna packaging requires two circuit substrates as stacks, and the overall thickness of the package is relatively thick, which cannot meet the requirements for miniaturization. In addition, silver glue is commonly used as antenna components, which is complex in manufacturing process and high in cost.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a schematic cross-sectional structure diagram of a semiconductor package device according to an embodiment of the present disclosure;

FIG. 2 is a schematic cross-sectional structure diagram of a semiconductor package device according to another embodiment of the present disclosure;

FIG. 3 is a schematic cross-sectional structure diagram of a semiconductor package device according to another embodiment of the present disclosure;

FIG. 4 is a schematic cross-sectional structure diagram of a semiconductor package device according to another embodiment of the present disclosure;

FIGS. 5A, 5B, 5C, 5D, 5E, 5F and 5G are schematic cross-sectional diagrams of a semiconductor package device according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one”.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

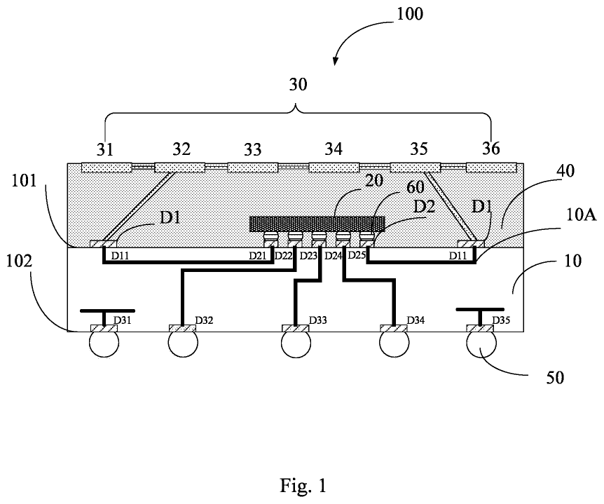

FIG. 1 shows a schematic cross-sectional structure diagram of a semiconductor package device according to an embodiment of the present disclosure. According to an embodiment of the present disclosure, the semiconductor packaging device 100 includes a circuit substrate 10, an electronic component 20, a plurality of antenna components 30, a sealing layer 40, and solder balls. The solder balls includes a first group of solder balls 60 and a second group of solder balls 50.

As shown in FIG. 1, the circuit substrate 10 has a circuit layer 10A. According to an embodiment of the present disclosure, the circuit substrate 10 can be formed layer by layer on a carrier first, then the carrier is removed after the formation of the redistributed layer 10 is completed. The formation of the circuit substrate 10 may involve multiple deposition or coating processes, patterning processes, and planarization processes. The deposition or coating processes can be used to form insulating layers or the circuit layers 10A. The deposition or coating processes may comprise a spin coating process, an electroplating process, an electroless process, a chemical vapor deposition (CVD) process, a physical vapor deposition (PVD) process, an atomic layer deposition (ALD) process, and other applicable processes and combinations thereof. The patterning process can be used to pattern the insulating layers and circuit layers 10A. The patterning process may comprise a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a flat top surface for the insulating layers and circuit layers 10A to facilitate subsequent processes. The planarization process may comprise a mechanical polishing process, a chemical mechanical polishing (CMP) process, or other applicable processes and combinations thereof.

The circuit substrate 10 can also be formed by an additive buildup process. The additive buildup process may comprise the alternating stacking of one or more dielectric layers and corresponding conductive patterns or traces of the circuit layers 10A. The conductive patterns or traces allow electrical traces out of the occupied space of the electronic device, or are in a fan-shaped layout allowing the electrical traces into the occupied space of the electronic device. The conductive patterns can be formed by a plating process such as an electroplating process or an electroless plating process. The conductive pattern may comprise a conductive material, such as copper or other plateable metals. The dielectric layer of the circuit substrate 10 can be made of a photo-definable organic dielectric such as polyimide (PI), benzocyclobutene (BCB), or polybenzoxazole (PBO). In other embodiments, the dielectric material of the circuit substrate 10 may also be an inorganic dielectric layer. The inorganic dielectric layer may comprise silicon nitride (Si3N4), silicon oxide (SiO2), or SiON. The inorganic dielectric layer can be formed by growing an inorganic dielectric layer using an oxidation or nitridation process.

According to the embodiment of the present disclosure, the circuit substrate 10 may further comprise a carrier, for example, a printed circuit substrate (PCB). The carrier can be formed by laminating and build-up methods, which are wholly conventional and will be fully appreciated by those of ordinary skill in the art. The material of the dielectric structure inside the carrier may comprise epoxy resin, phenolic resin, glass epoxy resin, polyimide, polyester, epoxy molding compound, or ceramic. The material of the wires inside the carrier may comprise copper, iron, nickel, gold, silver, palladium, or tin.

As shown in FIG. 1, the circuit substrate 10 includes a first surface 101 and a second surface 102 relative to the first surface 101. Between the first surface 101 and the second surface 102 is the circuit layer 10A. Both the first surface 101 and the second surface 102 are provided with bonding pads. The electronic component 20 is disposed on the first surface 101 and electrically connected to the bonding pads of the first surface 101. Specifically, the plurality of antenna components 30 span the electronic component 20 in a copper bridge manner and are electrically connected to the bonding pads of the first surface 101. The molding layer 40 is formed on the first surface 101 of the circuit substrate 10, surrounds and exposes the plurality of antenna components 30, and covers the electronic component 20. In the embodiment, one electronic component 20 and six antenna components 31, 32, 33, 34, 35, and 36 are taken as examples, but not limited to this. The number of electronic components 20 and antenna components 30 can be adjusted according to actual applications. The electronic component 20 is preferably a chip, which can be a wireless communication chip, such as a radio frequency integrated circuit (RFIC) or a microwave integrated circuit (MMIC), and can support, for example, near field communication (NFC) technology, radio frequency identification (RFID) technology, bluetooth, bluetooth low energy (BLE) zigbee or wireless hotspot Wi-Fi (i.e., Institute of Electrical and Electronics Engineers (IEEE) 802.11) technology, beacon internet protocol (IP), transmission control protocol (TCP), user packet protocol (UDP), device to device (D2D) protocol, long term evolution direct (LTE-D), narrow band internet of things (NB-IoT), LTE category M (LTE CAT-M), vehicle to X (V2X), or other such protocols described throughout the content of this case, or 3G, 4G, or 5G communication chips.

According to an embodiment of the present disclosure, the bonding pads on the first surface 101 of the circuit substrate 10 includes a first group of bonding pads D1 and a second group of bonding pads D2. The first group of bonding pads D1 is electrically connected to the second group of bonding pads D2. The bonding pads D3 on the second surface 102 of the circuit substrate 10 is electrically connected to the second group of bonding pads D2. The number of bonding pads in the first group of bonding pads D1, the second group of bonding pads D2, and the bonding pad D3 of the second side 102 depends on the actual application, such as a type of chip. In the embodiment, the first group of bonding pads D1 includes bonding pads D11, D12, the second group of bonding pads D2 includes bonding pads D21, D22, D23, D24, and D25, and the bonding pad D3 of the second surface 102 includes bonding pads D31, D32, D33, D34, and D35 as an example to explain the connection relationship better, but it is not limited to this. As shown in the figure, the bonding pad D11 in the first group of bonding pads D1 is electrically connected to the bonding pad D21 in the second group of bonding pads D2, and the bonding pad D12 in the first group of bonding pads D1 is electrically connected to the bonding pad D25 in the second group of bonding pads D2. The bonding pads D22, D23, and D24 in the second group of bonding pads D2 are respectively connected with the bonding pads D32, D33, and D34 of the bonding pads D3 in one-to-one correspondence.

The electronic component 20 is electrically connected to the second group of bonding pads D2. Referring to FIG. 1, the electronic component 20 is electrically connected to bonding pads D22-D24 of the second group of bonding pads D2. The antenna components 30 is electrically connected to the first group of bonding pads D1. Referring to FIG. 1, the antenna component 32 is electrically connected to the bonding pad D11 of the first group of bonding pads D1, and the antenna component 35 is electrically connected to the bonding pad D12 of the first group of bonding pads D1, so that the antenna components 30 are electrically connect to the electronic component 20.

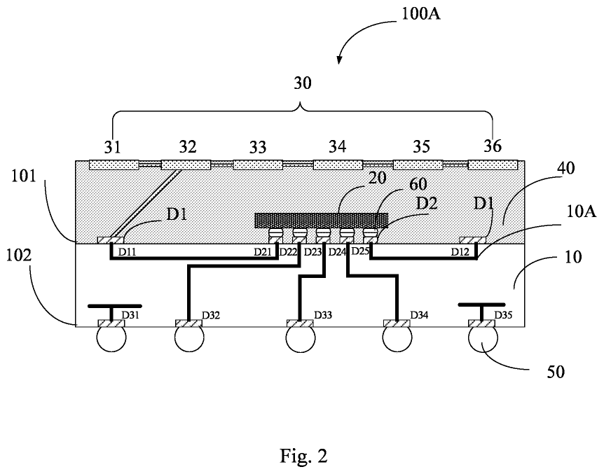

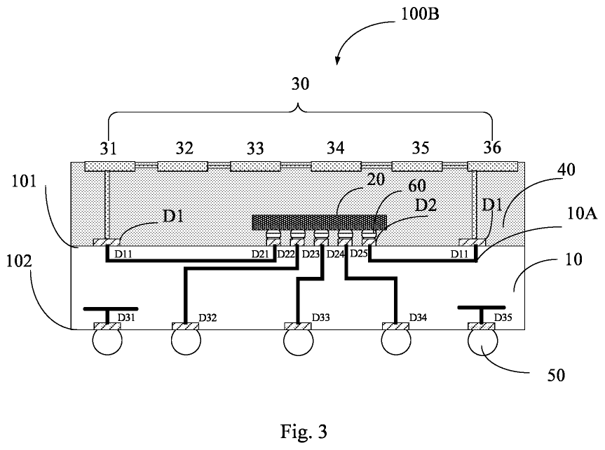

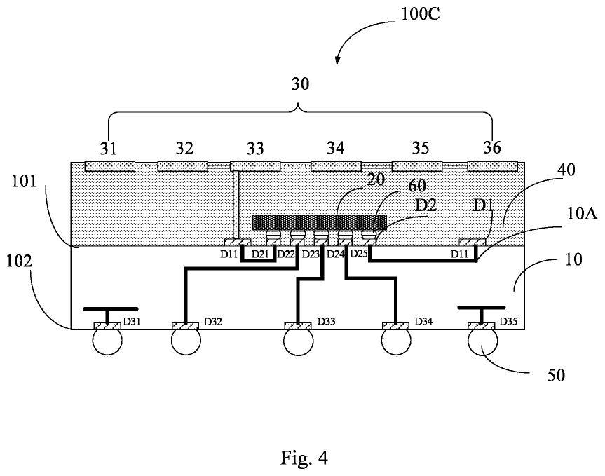

The antenna component 30 may be connected to the first group of bonding pads D1 in different manners. For example, as shown in FIG. 2, in the semiconductor package device 100A, only the antenna component 32 is electrically connected to the bonding pad D11 of the first group of bonding pads D1. As shown in FIG. 3, in the semiconductor package device 100B, the antenna component 31 is electrically connected to the bonding pad D11 of the first group of bonding pads D1, and the antenna component 36 is electrically connected to the bonding pad D12 of the first group of bonding pads D1. As shown in FIG. 4, in the semiconductor package device 100C, the first group of bonding pads D1 is electrically connected to the D21 in the second group of bonding pads D2 only through D11, that is only the antenna component 33 is electrically connected to the bonding pad D11 of the first group of bonding pads D1. Therefore, the antenna component 30 and the first group of bonding pads D1 can be connected in different ways, as long as the electrical connection between the antenna component 30 and the electronic component 20 is realized.

According to an embodiment of the present disclosure, the bonding pads D22-D24 in the second group of bonding pads D2 are printed with flux, and then the bonding pads D22-D24 are implanted with solder balls 60 through ball implantation, thereby fixing and electrically connecting the electronic component 20.

The molding layer 40 is formed on the circuit substrate 10, surrounds the antenna component 30, and exposes the top surface of the antenna component 30. The molding layer 40 also covers the electronic component 20. According to an embodiment of the present disclosure, the material of the molding layer 40 can be epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material.

According to the embodiment of the present disclosure, the second surface 102 of the circuit substrate 10 is provided with solder balls 50 electrically connected to the circuit layer 10A. The solder balls 50 can be implanted on the second surface 102 of the circuit substrate 10 through ball implantation. According to the embodiment of the present disclosure, the semiconductor packaging device 100 can be electrically connected to an external device (such as a printed circuit substrate) by these solder balls 50.

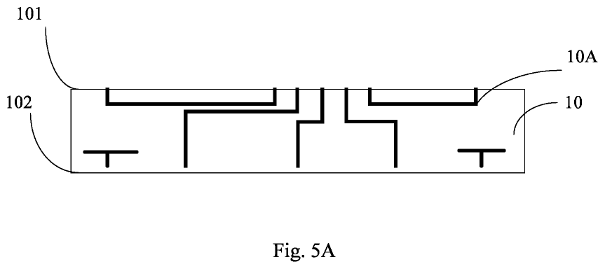

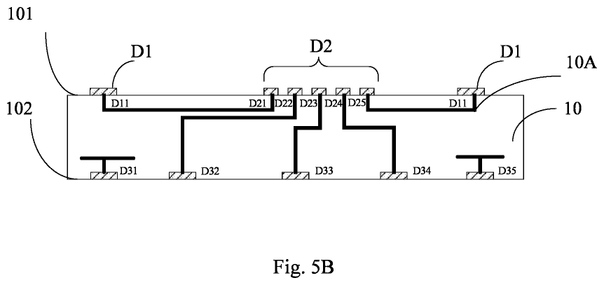

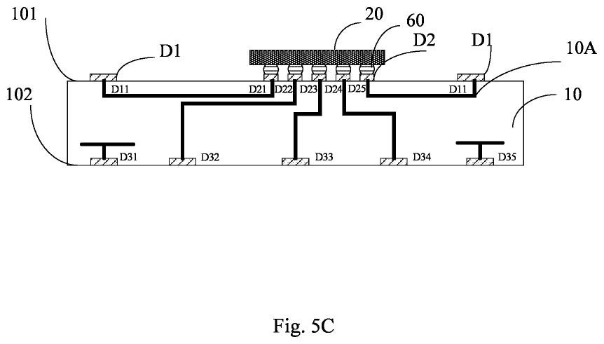

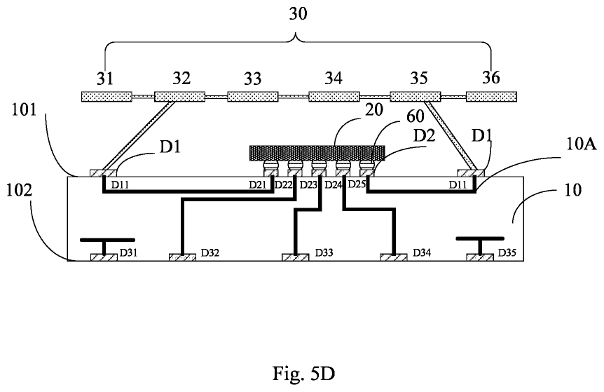

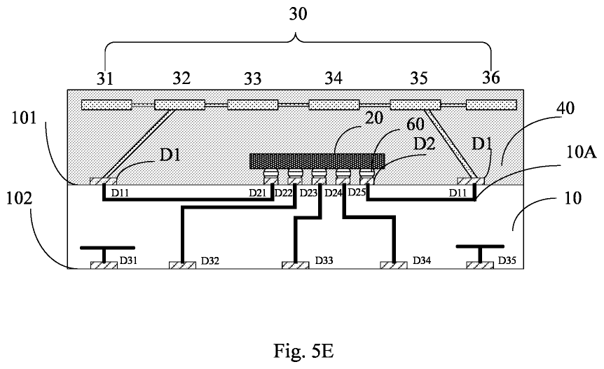

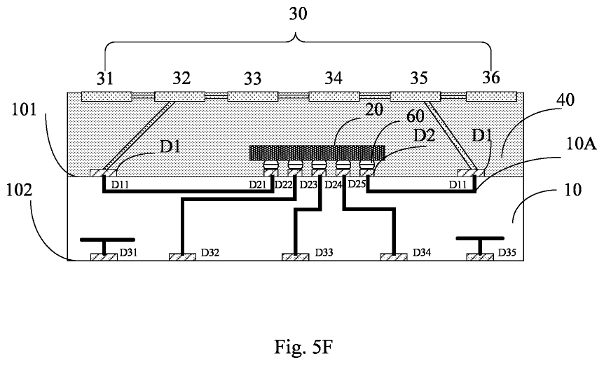

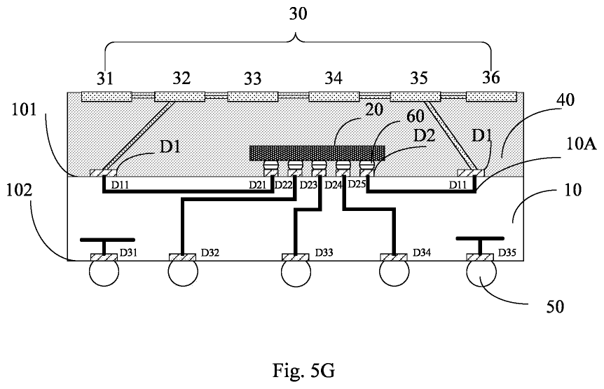

FIGS. 5A to 5G show schematic cross-sectional diagrams of a semiconductor package device according to an embodiment of the present disclosure. In FIG. 5A, a circuit substrate 10 is provided. The circuit substrate 10 includes a first surface 101, a second surface 102 relative to the first surface 101, and a circuit layer 10A between the first surface 101 and the second surface 102. According to an embodiment of the present disclosure, the circuit substrate 10 can be formed layer by layer on a carrier first, then the carrier is removed after the formation of the redistributed layer 10 is completed. The formation of the circuit substrate 10 may involve multiple deposition or coating processes, patterning processes, and planarization processes. The deposition or coating processes can be used to form insulating layers or the circuit layers 10A. The deposition or coating processes may comprise a spin coating process, an electroplating process, an electroless process, a chemical vapor deposition (CVD) process, a physical vapor deposition (PVD) process, an atomic layer deposition (ALD) process, and other applicable processes and combinations thereof. The patterning process can be used to pattern the insulating layers and circuit layers 10A. The patterning process may comprise a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a flat top surface for the insulating layers and circuit layers 10A to facilitate subsequent processes. The planarization process may comprise a mechanical polishing process, a chemical mechanical polishing (CMP) process, or other applicable processes and combinations thereof.

The circuit substrate 10 can also be formed by an additive buildup process. The additive buildup process may comprise the alternating stacking of one or more dielectric layers and corresponding conductive patterns or traces of the circuit layers 10A. The conductive patterns or traces allow electrical traces out of the occupied space of the electronic device, or are in a fan-shaped layout allowing the electrical traces into the occupied space of the electronic device. The conductive patterns can be formed by a plating process such as an electroplating process or an electroless plating process. The conductive pattern may comprise a conductive material, such as copper or other plateable metals. The dielectric layer of the circuit substrate 10 can be made of a photo-definable organic dielectric such as polyimide (PI), benzocyclobutene (BCB), or polybenzoxazole (PBO). In other embodiments, the dielectric material of the circuit substrate 10 may also be an inorganic dielectric layer. The inorganic dielectric layer may comprise silicon nitride (Si3N4), silicon oxide (SiO2), or SiON. The inorganic dielectric layer can be formed by growing an inorganic dielectric layer using an oxidation or nitridation process.

According to the embodiment of the present disclosure, the circuit substrate 10 may further comprise a carrier, for example, a printed circuit substrate (PCB). The carrier can be formed by laminating and build-up methods, which are wholly conventional and will be fully appreciated by those of ordinary skill in the art. The material of the dielectric structure inside the carrier may comprise epoxy resin, phenolic resin, glass epoxy resin, polyimide, polyester, epoxy molding compound, or ceramic. The material of the wires inside the carrier may comprise copper, iron, nickel, gold, silver, palladium, or tin.

Next, in FIG. 5B, bonding pads are disposed on the first surface 101 and the second surface 102. the bonding pads on the first surface 101 of the circuit substrate 10 includes a first group of bonding pads D1 and a second group of bonding pads D2. The first group of bonding pads D1 is electrically connected to the second group of bonding pads D2. The bonding pads D3 on the second surface 102 of the circuit substrate 10 is electrically connected to the second group of bonding pads D2. The number of bonding pads in the first group of bonding pads D1, the second group of bonding pads D2, and the bonding pad D3 of the second side 102 depends on the actual application, such as a type of chip. In the embodiment, the first group of bonding pads D1 includes bonding pads D11, D12, the second group of bonding pads D2 includes bonding pads D21, D22, D23, D24, and D25, and the bonding pad D3 of the second surface 102 includes bonding pads D31, D32, D33, D34, and D35 as an example to explain the connection relationship better, but it is not limited to this. As shown in the figure, the bonding pad D11 in the first group of bonding pads D1 is electrically connected to the bonding pad D21 in the second group of bonding pads D2, and the bonding pad D12 in the first group of bonding pads D1 is electrically connected to the bonding pad D25 in the second group of bonding pads D2. The bonding pads D22, D23, and D24 in the second group of bonding pads D2 are respectively connected with the bonding pads D32, D33, and D34 of the bonding pads D3 in one-to-one correspondence.

Next, in FIG. 5C, an electronic component 20 is disposed on the first surface 101 and electrically connected to the bonding pads on the first surface 101. In FIG. 5C, only one electronic component is taken as an example, but not limited to this. The number of electronic components depends on the actual application. In the embodiment, the electronic component 20 is electrically connected to the D22-D24 of the second group of bonding pads D2. Specifically, the bonding pads D22-D24 in the second group of bonding pads D2 are printed with solder flux, and then the solder ball 60 is implanted on the bonding pads D22-D24 through ball implantation, thereby fixing and electrically connecting the electronic components 20. The electronic component 20 is preferably a chip, which can be a wireless communication chip, such as a radio frequency integrated circuit (RFIC) or a microwave integrated circuit (MMIC), and can support, for example, near field communication (NFC) technology, radio frequency identification (RFID) technology, bluetooth, bluetooth low energy (BLE) zigbee or wireless hotspot Wi-Fi (i.e., Institute of Electrical and Electronics Engineers (IEEE) 802.11) technology, beacon internet protocol (IP), transmission control protocol (TCP), user packet protocol (UDP), device to device (D2D) protocol, long term evolution direct (LTE-D), narrow band internet of things (NB-IoT), LTE category M (LTE CAT-M), vehicle to X (V2X), or other such protocols described throughout the content of this case, or 3G, 4G, or 5G communication chips.

Next, in FIG. 5D, a plurality of antenna components 30 spanning the electronic component 20 in a copper bridge manner are disposed, wherein the plurality of antenna components 30 are electrically connected to the bonding pads on the first surface 101. In FIG. 5D, taking 6 antenna components 31-36 as an example, but not limited to this, the number of electronic components depends on the actual application. In the embodiment, the antenna component 32 is electrically connected to the bonding pad D11 of the first group of bonding pads D1, and the antenna component 35 is electrically connected to the bonding pad D12 of the first group of bonding pads D1, so that the antenna components 30 are electrically connect to the electronic component 20. The antenna component 30 may be connected to the first group of bonding pads D1 in different manners. For example, as shown in FIG. 2, in the semiconductor package device 100A, only the antenna component 32 is electrically connected to the bonding pad D11 of the first group of bonding pads D1. As shown in FIG. 3, in the semiconductor package device 100B, the antenna component 31 is electrically connected to the bonding pad D11 of the first group of bonding pads D1, and the antenna component 36 is electrically connected to the bonding pad D12 of the first group of bonding pads D1. As shown in FIG. 4, in the semiconductor package device 100C, the first group of bonding pads D1 is electrically connected to the D21 in the second group of bonding pads D2 only through D11, that is only the antenna component 33 is electrically connected to the bonding pad D11 of the first group of bonding pads D1. Therefore, the antenna component 30 and the first group of bonding pads D1 can be connected in different ways, as long as the electrical connection between the antenna component 30 and the electronic component 20 is realized.

Next, in FIG. 6E, the molding layer 40 is formed on the first surface 101 of the circuit substrate 10 and covers the electronic component 20 and the antenna component 30. According to an embodiment of the present disclosure, the material of the molding layer 40 can be epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material.

Next, in FIG. 5F, the molding layer 40 is polished to expose the top of the antenna component 30. Specifically, the molding layer 40 is polished by a planarization process until the top of the antenna component 30 is exposed. As shown in FIG. 5F, the electronic component 20 is still covered by the molding layer 40.

Next, in FIG. 5G, a second group of soldering balls 50 are implanted on the second surface 102, and the second group of soldering balls 50 is electrically connected to the bonding pads on the second surface 102. The second group of solder balls 50 can be implanted on the second surface 102 of the circuit substrate 10 through ball implantation. According to the embodiment of the present disclosure, the semiconductor packaging device 100 can be electrically connected to an external device (such as a printed circuit substrate) by these solder balls 50.

According to an embodiment of the present disclosure, the electronic components and antenna components are covered with a molding layer, while exposing the top of the antenna components, reducing the number of substrates, thereby achieving product miniaturization. Moreover, the plurality of antenna components spans the electronic component in a copper bridge manner and are electrically connected to the bonding pads on the first surface, which is simple in manufacturing process and low in cost.

Many details are often found in the relevant art and many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A semiconductor package device comprising:
a circuit substrate comprising a first surface and a second surface opposite to the first surface, and a circuit layer disposed between the first surface and the second surface, wherein both the first surface and the second surface are provided with bonding pads;
an electronic component disposed on the first surface and electrically connected to the bonding pads of the first surface;
a plurality of antenna components spanning the electronic component in a copper bridge manner and electrically connected to the bonding pads on the first surface; and
a molding layer formed on the first surface of the circuit substrate, wherein the circuit substrate surrounds and exposes the plurality of antenna components, and covers the electronic component.

2. The semiconductor package device according to claim 1, wherein:
the bonding pads of the first surface comprises a first group of bonding pads and a second group of bonding pads;
the first group of bonding pads are electrically connected to the second group of bonding pads;
the bonding pads of the second surface are electrically connected to the second group of bonding pads.

3. The semiconductor package device according to claim 2, wherein:
the electronic component is electrically connected to the second group of bonding pads;
the antenna components are electrically connected to the first group of bonding pads, to electrically connect the antenna components to the electronic component.

4. The semiconductor package device according to claim 2, wherein the second group of bonding pads is fixed and electrically connected to the electronic component by printing flux and implanting a first group of solder balls.

5. The semiconductor package device according to claim 1, further comprising:
solder balls implanted on the second surface and electrically connected to the bonding pads of the second surface.

6. A manufacturing method for semiconductor packaging device, comprising:
disposing a circuit substrate, wherein the circuit substrate comprises a first surface and a second surface opposite to the first surface, and a circuit layer disposed between the first surface and the second surface;
disposing bonding pads on the first surface and the second surface;
disposing an electronic component on the first surface, and electrically connecting the electronic component to the bonding pads of the first surface;
disposing a plurality of antenna components by spanning the plurality of antenna components across the electronic component in a copper bridge manner, wherein the plurality of antenna components are electrically connected to the bonding pads on the first surface;
forming a molding layer on the first surface to cover the electronic component and the plurality of antenna components; and
polishing the molding layer to expose a top of the plurality of antenna components.

7. The manufacturing method for semiconductor packaging device according to claim 6, wherein:
the bonding pads of the first surface comprises a first group of bonding pads and a second group of bonding pads;
the first group of bonding pads are electrically connected to the second group of bonding pads;
the bonding pads of the second surface are electrically connected to the second group of bonding pads.

8. The manufacturing method for semiconductor packaging device according to claim 7, wherein the disposing an electronic component on the first surface, and electrically connecting the electronic component to the bonding pads of the first surface comprises:
electrically connecting the electronic component to the second group of bonding pads;
electrically connecting the plurality of antenna components to the first group of bonding pads so that the plurality of antenna components are electrically connect to the electronic component.

9. The manufacturing method for semiconductor packaging device according to claim 8, wherein electrically connecting the electronic component to the second group of bonding pads comprises:
printing soldering flux on the second group of bonding pads;
implanting a first group of soldering balls on the second group of bonding pads;
disposing the electronic component on the second group of bonding pads.

10. The manufacturing method for semiconductor packaging device according to claim 6, further comprising:
implanting a second group of soldering balls on the second surface, wherein the second group of soldering balls is electrically connected to the bonding pads on the second surface.
